(19) United States
(12) Patent Application Publication
(10) Pub. No.: US 2026/0093139 A1
(43) Pub. Date: Apr. 2, 2026

(54) DISPLAY APPARATUS

(71) Applicant: SAMSUNG ELECTRONICS CO., LTD., Suwon-si (KR)

(72) Inventors: Kangpyo BAE, Suwon-si (KR); Eunjong CHOI, Suwon-si (KR)

(73) Assignee: SAMSUNG ELECTRONICS CO., LTD., Suwon-si (KR)

(21) Appl. No.: 19/335,691

(22) Filed: Sep. 22, 2025

Related U.S. Application Data
(63) Continuation of application No. PCT/KR2025/011529, filed on Aug. 1, 2025.

(30) Foreign Application Priority Data
Sep. 28, 2024 (KR) 10-2024-0132271

(51) Int. Cl. G02F 1/1333; G02F 1/133; H05K 1/18; H05K 5/00; H05K 5/02; H05K 5/03

(52) U.S. Cl. CPC G02F 1/133317; G02F 1/13306; G02F 1/133314; H05K 1/18; H05K 5/0018; H05K 5/0247; H05K 5/03; H05K 2201/10136

(57) ABSTRACT

A display apparatus may include: a display panel; a chassis configured to cover a rear side of the display panel and support the display panel, the chassis including a first rib hole; a chassis holder configured to connect to a lower portion of the chassis, the chassis holder including a second rib hole configured to overlap with the first rib hole while the chassis holder is connected to the chassis; and a rear cover configured to connect to a rear side of the chassis and a rear side of the chassis holder while the chassis holder is connected to the chassis, wherein the rear cover includes a rib, the rib configured to be inserted into the second rib hole and the first rib hole by being received in the first rib hole through the second rib hole while the rear cover is connected to the chassis and the chassis holder.

### CROSS-REFERENCE TO RELATED APPLICATIONS

This application is bypass continuation of International Patent Application No. PCT/KR2025/011529, filed in the Korean Intellectual Property Office on Aug. 1, 2025, which claims priority to Korean Patent Application No. 10-2024-0132271, filed in the Korean Intellectual Property Office on Sep. 28, 2024, the disclosures of which are incorporated herein by reference in their entireties.

### BACKGROUND

### 1. Field

Some embodiments of the present disclosure relate to a display apparatus.

### 2. Description of Background Art

A display apparatus is a kind of an output apparatus that converts obtained or stored electrical information into visual information and displays the visual information to a user, and the display apparatus may be used in various fields, such as a home or a workplace.

The display apparatus may include a monitor apparatus connected to a personal computer or a server computer, a portable computer device, a navigation terminal device, a general television apparatus, an Internet Protocol television (IPTV), a portable terminal device (e.g., a smart phone, a tablet PC, a personal digital assistant (PDA) or a cellular phone), various display apparatuses used to reproduce images (e.g., advertisements or movies in an industrial field), or various kinds of audio/video systems.

The display apparatus may include a light source module to convert electrical information into visual information, and the light source module may include a plurality of light sources to independently emit light.

Each of the plurality of light sources may include a light emitting diode (LED) or an organic light emitting diode (OLED). For example, the LED or the OLED may be mounted on a circuit board or substrate.

### SUMMARY

According to some embodiments of the present disclosure, a display apparatus with improved assemblability may be provided.

According to some embodiments of the present disclosure, a display apparatus with improved productivity may be provided.

According to some embodiments of the present disclosure, a display apparatus capable of being assembled without a screw may be provided.

According to some embodiments of the present disclosure, a display apparatus having enhanced coupling strength between components may be provided.

Additional aspects of the present disclosure will be set forth in part in the description which follows and, in part, will be understood from the description, or may be learned by practice of the present disclosure.

According to some embodiments of the present disclosure, a display apparatus may include: a display panel; a chassis configured to cover a rear side of the display panel and support the display panel, the chassis including a first rib hole; a chassis holder configured to connect to a lower portion of the chassis, the chassis holder including a second rib hole configured to overlap with the first rib hole while the chassis holder is connected to the chassis; and a rear cover configured to connect to a rear side of the chassis and a rear side of the chassis holder while the chassis holder is connected to the chassis, wherein the rear cover includes a rib, the rib being configured to be inserted into the second rib hole and the first rib hole by being received in the first rib hole through the second rib hole while the rear cover is connected to the chassis and the chassis holder.

According to some embodiments of the present disclosure, a display apparatus may include: a display panel; a chassis configured to support the display panel; a first printed circuit board on a rear side of the chassis, the first printed circuit board being configured to control the display panel; a second printed circuit board on the rear side of the chassis, the second printed circuit board including a terminal configured to receive a signal or power from an outside of the display apparatus; a chassis holder configured to be connected to or separated from the chassis by sliding relative to the chassis, the chassis holder being further configured to cover the first printed circuit board while the chassis holder is connected to the chassis; and a rear cover configured to be connected to the rear side of the chassis and a rear side of the chassis holder while the chassis holder is connected to the chassis, the rear cover being further configured to cover the second printed circuit board while the rear cover is connected to the chassis and the chassis holder.

According to some embodiments of the present disclosure, a display apparatus may include: a display panel; a chassis that covers a rear side of the display panel and supports the display panel, the chassis including a first rib hole; a chassis holder that is connected to a lower portion of the chassis, the chassis holder including a second rib hole that overlaps with the first rib hole; and a rear cover that is connected to a rear side of the chassis and a rear side of the chassis holder while the chassis holder is connected to the chassis, wherein the rear cover includes a rib, the rib being within the second rib hole and the first rib hole by being received in the first rib hole through the second rib hole while the rear cover is connected to the chassis and the chassis holder.

### BRIEF DESCRIPTION OF DRAWINGS

FIG. 1 illustrates a display apparatus according to an embodiment of the present disclosure.

FIG. 2 illustrates the display apparatus according to an embodiment of the present disclosure.

FIG. 3 is an exploded view of the display apparatus according to an embodiment of the present disclosure.

FIG. 4 is an exploded view of the display apparatus according to an embodiment of the present disclosure.

FIG. 5 illustrates a chassis according to an embodiment of the present disclosure.

FIG. 6 illustrates the chassis illustrated in FIG. 5 when viewed from a direction different from FIG. 5.

FIG. 7 illustrates the chassis illustrated in FIG. 5 when viewed from a direction different from FIGS. 5 and 6.

FIG. 8 illustrates a chassis holder according to an embodiment of the present disclosure.

FIG. 9 is an enlarged view of a portion A illustrated in FIG. 8.

FIG. 10 illustrates a rear cover according to an embodiment of the present disclosure.

FIG. 11 is an enlarged view of a portion B illustrated in FIG. 10.

FIG. 12 is an enlarged view of a portion C illustrated in FIG. 10.

FIG. 13 is an enlarged view of a portion D illustrated in FIG. 10.

FIG. 14 illustrates a state in which the chassis holder is separated from the chassis in the display apparatus according to an embodiment of the present disclosure.

FIG. 15 illustrates a state in which the chassis holder is coupled to the chassis in the display apparatus according to an embodiment of the present disclosure.

FIG. 16 is a cross-sectional view taken along a line I-I′ illustrated in FIG. 15.

FIG. 17 illustrates a state in which the rear cover is separated from the chassis and the chassis holder in the display apparatus according to an embodiment of the present disclosure.

FIG. 18 illustrates a state in which the rear cover is coupled to the chassis and the chassis holder in the display apparatus according to an embodiment of the present disclosure.

FIG. 19 is a cross-sectional view taken along a line II-II′ illustrated in FIG. 18.

FIG. 20 is a cross-sectional view taken along a line III-III′ illustrated in FIG. 18.

FIG. 21 is a cross-sectional view taken along a line IV-IV′ illustrated in FIG. 18.

### SPECIFICATION

The various example embodiments described in the present disclosure and terminology used herein are not intended to limit the present disclosure. Instead, all modifications, equivalents, and alternatives of the example embodiments and terminology are within the spirit and scope of the present disclosure.

In the description of the drawings, like numbers refer to like elements throughout the description of the drawings.

The singular forms preceded by “a,” “an,” and “the” corresponding to an item are intended to include the plural forms as well unless the context clearly indicates otherwise.

In the disclosure, a phrase such as “A or B,” “at least one of A and B,” “at least one of A or B,” “A, B or C,” “at least one of A, B and C,” and “at least one of A, B, or C” may include any one of the items listed together in the corresponding phrase of the phrases, or any possible combination thereof.

The term “and/or” includes combinations of one or all of a plurality of associated listed items.

The terms of “part,” “module,” and “member” may be implemented in hardware or software. In some embodiments, a plurality of “parts,” “modules,” and “members” may be implemented as a single component. In some embodiments, a single “part,” “module,” and “member” may include multiple components.

As used herein, such terms as “1st” and “2nd,” or “first” and “second” may be used to simply distinguish a corresponding component from another, and does not limit the components in other aspect (e.g., importance or order).

When one (e.g., a first) element is referred to as being “coupled” or “connected” to another (e.g., a second) element with or without the term “functionally” or “communicatively,” it means that the one element is connected to the other element directly, wirelessly, or via a third element.

It will be understood that the terms “include,” “comprise. ” and/or “have” when used in this specification, specify the presence of stated features, integers, steps, operations, elements, and/or components, but do not preclude the presence or addition of one or more other features, integers, steps, operations, elements, components, and/or groups thereof.

It is to be understood that if a certain component is referred to as being “coupled with,” “coupled to,” “supported on,” or “in contact with” another component, it means that the component may be coupled, supported, or in contact with the other component directly or indirectly via a third component.

It will also be understood that when a component is referred to as being “on” another component, it may be directly on the other component or intervening components may also be present.

Meanwhile, the terms “front,” “rear,” “left,” “right,” “upper,” and “lower,” as used in the following description, are defined based on the drawings, and these terms do not limit the shape or position of each component. For example, “front” and “rear” may be defined with reference to the Z-axis shown in the drawings. Similarly, “left” and “right” may be defined with reference to the Y-axis shown in the drawings. Likewise, “upper” and “lower” may be defined with reference to the Z-axis shown in the drawings.

Hereinafter, non-limiting example embodiments of the present disclosure will be described in detail with reference to the accompanying drawings.

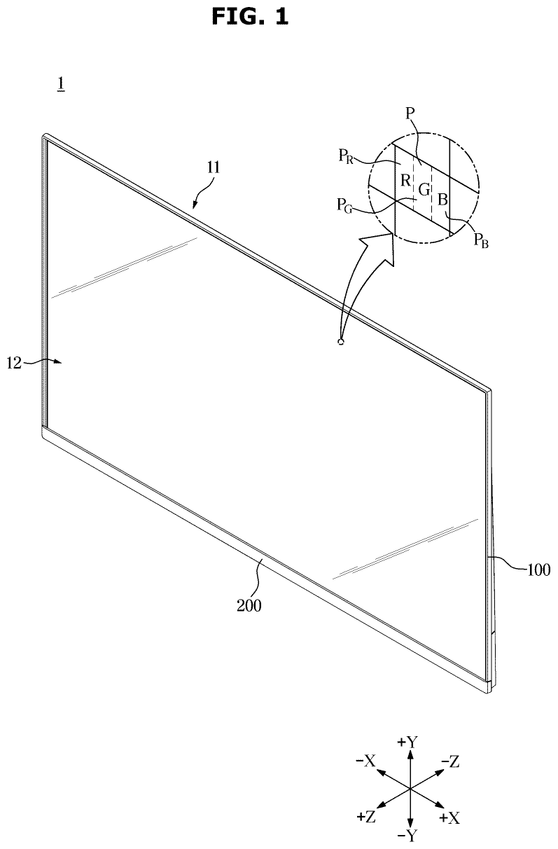

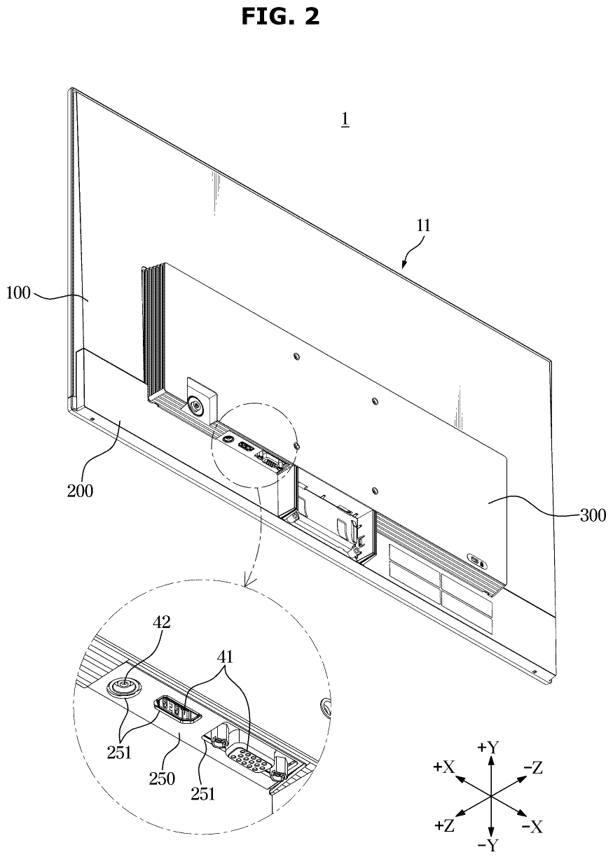

FIG. 1 is a view of a display apparatus according to an embodiment of the present disclosure. FIG. 2 illustrates the display apparatus according to an embodiment of the present disclosure.

A display apparatus 1 according to an embodiment of the present disclosure may be a device that processes an image signal received from an outside and visually displays the processed image. For example, the display apparatus 1 may be implemented in various forms, such as a television (TV), a monitor which is a type of computer output device, a portable multimedia device, and a portable communication device, and the display apparatus 1 is not limited in the type thereof as long as the display apparatus is configured to visually display an image.

The display apparatus 1 may be a large format display (LFD) installed outdoors, such as a roof of a building or a bus stop. The outdoor is not limited to the outside of a building, and thus the display apparatus 1 according to an embodiment may be installed in any place as long as the display apparatus is accessed by a large number of people, even indoors, such as subway stations, shopping malls, movie theaters, companies, and stores.

The display apparatus 1 may receive content data including video signals and audio signals from various content sources, and output video and audio corresponding to the video signals and the audio signals. For example, the display apparatus 1 may receive content data through a broadcast reception antenna or cable, receive content data from a content playback device, or receive content data from a content providing server of a content provider.

The display apparatus 1 may display an image corresponding to video data and output sound corresponding to audio data. For example, the display apparatus 1 may restore a plurality of image frames included in the video data and continuously display the plurality of image frames. Further, the display apparatus 1 may restore an audio signal included in the audio data and continuously output sound according to the audio signal

The display apparatus 1 may include a main body 11, and a screen 12 provided to display an image.

The display apparatus 1 may be installed on an indoor or outdoor floor or furniture in a standing manner, or may be installed on a wall or inside a wall in a wall-mounted manner. For example, the display apparatus 1 may include a leg provided at a lower portion of the main body 11 to allow the display apparatus 1 to be installed on the indoor or outdoor floor or furniture in the standing manner.

The main body 11 may form an appearance of the display apparatus 1. A component configured to allow the display apparatus 1 to display the image and to perform various functions may be provided in the main body 11.

The display apparatus 1 may be configured to display the image. Particularly, the screen 12 may be formed on a front surface of the main body 11, and the display apparatus 1 may display the image on the screen 12. For example, the screen 12 may display a still image or a moving image. Further, the screen 12 may display a two-dimensional plane image or a three-dimensional image using binocular parallax of the user.

A plurality of pixels P may be formed on the screen 12. The image displayed on the screen 12 may be formed by a combination of the lights emitted from the plurality of pixels P. For example, the image may be formed on the screen 12 by combining light emitted from the plurality of pixels P as a mosaic.

Each of the plurality of pixels P may emit different brightness and different color of light. Particularly, the plurality of pixels P may include sub-pixels, respectively, and the sub-pixels may include a red sub-pixel P_{R} emitting red light, a green sub-pixel PG emitting green light, and a blue sub-pixel P_{B} emitting blue light. For example, the red light may represent a light beam having a wavelength of approximately 620 nanometers (nm, one billionth of a meter) to 750 nm, the green light may represent a light beam having a wavelength of approximately 495 nm to 570 nm, and the blue light may represent a light beam having a wavelength of approximately 450 nm to 495 nm.

By combining the red light of the red sub-pixel P_{R}, the green light of the green sub-pixel P_{G}, and the blue light of the blue sub-pixel P_{B}, each of the plurality of pixels P may emit a different brightness and a different color of light.

The display apparatus 1 may include an input terminal 41. The input terminal 41 may be provided on a rear side of the main body 11. The input terminal 41 may receive various signals (e.g., video signals) from the outside. For example, the input terminal 41 may be provided as various terminals such as High-Definition Multimedia Interface (HDMI), Video Graphics Array (VGA), and the like. There is no limitation in the number of input terminals 41, and one or more input terminals 41 may be provided.

The display apparatus 1 may include a power terminal 42. The display apparatus 1 may receive power from an external source through the power terminal 42. For example, the power terminal 42 may be electrically connected to a separate adapter or battery. There is no limitation on the number of power terminals 42, and one or more power terminals 42 may be provided.

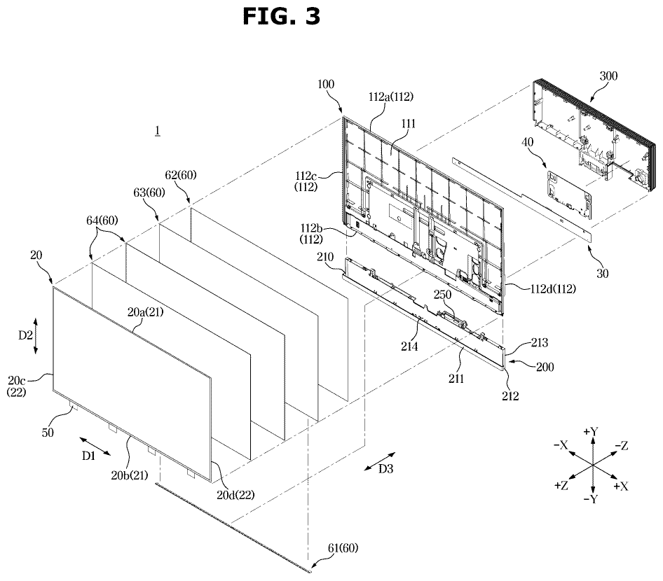

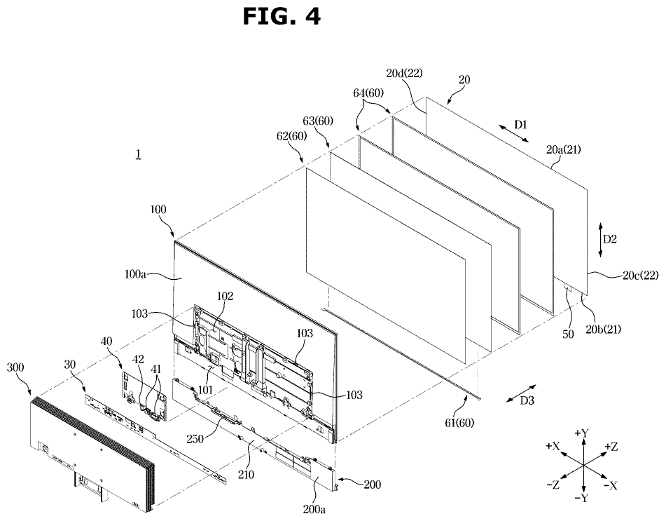

FIG. 3 is an exploded view of the display apparatus according to an embodiment of the present disclosure. FIG. 4 is an exploded view of the display apparatus according to an embodiment of the present disclosure.

Referring to FIGS. 3 and 4, various components for generating an image on the screen 12 may be provided inside the main body 11 of the display apparatus 1 according to an embodiment of the present disclosure.

The display apparatus 1 may include a display panel 20. The display panel 20 may be configured to display an image. The screen 12 described in FIG. 1 may be formed on a front surface of the display panel 20.

The display panel 20 may have a substantially quadrangle shape. The display panel 20 may include a pair of first sides 21 extending along a first direction D1, and a pair of second sides 22 extending along a second direction D2. The second direction D2 may be a direction intersecting the first direction D1. For example, the first direction D1 may be a horizontal direction (e.g., X direction) and the second direction D2 may be a vertical direction (e.g., Y direction). The display panel 20 may include an upper border 20a, a lower border 20b, a left border 20c, and a right border 20d. The upper border 20a and the lower border 20b may be referred to as the pair of first sides 21, and the left border 20c and the right border 20d may be referred to as the pair of second sides 22. For example, the first side 21 may be a long side, and the second side 22 may be a short side. However, embodiments of the present disclosure are not limited to the above-described example, and the display panel 20 may have a square shape in which a length of the first side 21 and a length of the second side 22 are the same or almost the same.

The display panel 20 may be provided in various sizes. A ratio of the long side to the short side of the display panel 20 is not limited to general cases such as 16:9 and 4:3, and may be provided in any ratio.

For example, the display panel 20 may be composed of a liquid crystal display (LCD) panel. The display panel 20 may display an image using liquid crystals that exhibit optical properties according to changes in voltage and temperature. The display panel 20 may be composed of a thin film transistor (TFT) substrate, a color filter substrate, and liquid crystals injected between the thin film transistor substrate and the color filter substrate.

However, embodiments of the present disclosure are not limited to the above-described example, and the display panel 20 may be implemented as a self-luminous display panel, and in this case, the display apparatus 1 may not include a backlight unit 60.

The display apparatus 1 may include a first printed circuit board 30. The first printed circuit board 30 may be configured to control the display panel 20. The first printed circuit board 30 may be configured to provide an image signal to the display panel 20. The first printed circuit board 30 may be configured to output a signal for driving a plurality of pixels P. For example, the first printed circuit board 30 may be referred to as a source board.

The first printed circuit board 30 may be disposed on a rear side 100a of a chassis 100 to be described later. The first printed circuit board 30 may be detachably mounted on a first mounting portion 101 of the chassis 100 to be described later.

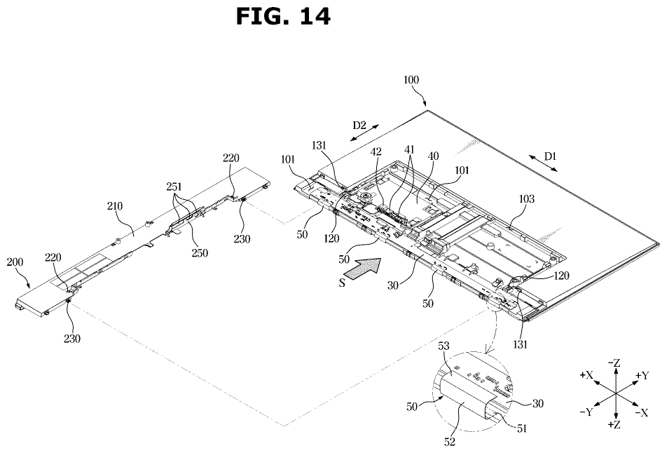

The display apparatus 1 may include a film cable 50. The film cable 50 may transmit a video signal output from the first printed circuit board 30 to the display panel 20. The film cable 50 may connect the display panel 20 and the first printed circuit board 30. A first end of the film cable 50 may be connected to the display panel 20, and a second end of the film cable 50 may be connected to the first printed circuit board 30. The first end of the film cable 50 may be provided adjacent to the lower border 20b of the display panel 20. The film cable 50 may be provided with a flexible material. The film cable 50 may be bent to connect the display panel 20 and the first printed circuit board 30 (refer to FIG. 14). For example, the film cable 50 may be implemented in the form of a chip on film (COF), and in this case, the film cable 50 may be referred to as a COF.

The display apparatus 1 may include a second printed circuit board 40. The second printed circuit board 40 may control each of the components of the display apparatus 1. For example, the second printed circuit board 40 may be configured to control an operation of the backlight unit 60 and/or an operation of the display panel 20. The second printed circuit board 40 may receive various signals and/or power from the outside. The second printed circuit board 40 may include the terminals (e.g., the input terminal 41 and/or power terminal 42) that receive signals and/or power from the outside. The second printed circuit board 40 may include the input terminal 41 and/or the power terminal 42. For example, the second printed circuit board 40 may analyze, convert, and/or process an image signal received through the input terminal 41. For example, the second printed circuit board 40 may convert power received through the power terminal 42 into a voltage required for each component and provide the voltage. For example, the second printed circuit board 40 may be referred to as a main board.

The second printed circuit board 40 may be disposed on the rear side 100a of the chassis 100 to be described later. The second printed circuit board 40 may be detachably mounted on a second mounting portion 102 of the chassis 100 to be described later. For example, the second printed circuit board 40 may be disposed above the first printed circuit board 30.

The display apparatus 1 may include the backlight unit 60. The backlight unit 60 may be configured to emit light toward the display panel 20. The backlight unit 60 may be arranged at the rear of the display panel 20. The backlight unit 60 may be configured to emit light toward the front on which the display panel 20 is located. The display panel 20 may block or transmit light emitted from the backlight unit 60.

The backlight unit 60 may include a light source device 61. The light source device 61 may generate and emit light. For example, the light source device 61 may be configured to emit monochromatic light or white light. The light source device 61 may be configured to provide light to the display panel 20.

In FIGS. 3 and 4, it is illustrated that a single light source device 61 is provided, but embodiments of the present disclosure are not limited thereto. A plurality of the light source devices 61 may be provided.

The light source device 61 may be referred to as a light source module, a light source unit, a light source assembly, and the like.

The backlight unit 60 may include a reflective sheet 62. The reflective sheet 62 may be configured to reflect light. The reflective sheet 62 may reflect light forward (e.g., in the +Z direction) or in a direction close to the forward direction. The reflective sheet 62 may reflect light emitted from the light source device 61 or may re-reflect light, which is emitted backward from the display panel 20 or the like, toward the display panel 20.

The backlight unit 60 may include a light guide plate 63. The light guide plate 63 may evenly disperse light emitted from the light source device 61. The light guide plate 63 may convert light emitted from the light source device 61 into surface light and guide the surface light to the display panel 20. The light guide plate 63 may be formed of a Poly Methyl Methacrylate Acrylate (PMMA) material. Various patterns may be formed on the light guide plate 63 to change a path of light.

The backlight unit 60 may include an optical sheet 64. The optical sheet 64 may be configured to further improve the luminance and the uniformity of the luminance of the emitted light. The optical sheet 64 may be configured to refract and scatter light emitted from the front surface of the light guide plate 63. For example, the optical sheet 64 may include various types of sheets such as a diffusion sheet, a prism sheet, a reflective polarizing sheet, and a quantum dot sheet.

In FIGS. 3 and 4, it is illustrated that two optical sheets 64 are provided, but there is no limitation on the number of optical sheets 64. Alternatively, one or more optical sheets 64 may be provided.

Meanwhile, although the drawing illustrates an edge display method, embodiments of the present disclosure are not limited thereto. The contents of the present disclosure may also be applied to a direct display method.

The display apparatus 1 may include the chassis 100. The chassis 100 may cover the rear side of the display panel 20. The chassis 100 may support the display panel 20. The chassis 100 may cover a rear side of the backlight unit 60. The chassis 100 may support the backlight unit 60. The chassis 100 may be provided to form a portion of a rear exterior of the display apparatus 1.

For example, the chassis 100 may be formed through injection molding. The chassis 100 may be an injection molded product. The chassis 100 may include a plastic material. In comparison with a chassis that includes a metal material and is formed through press molding, the chassis 100 may be light and low in cost. Accordingly, the display apparatus 1 may be lightweight.

The display apparatus 1 may include a chassis holder 200. The chassis holder 200 may be configured to be coupleable to the chassis 100. For example, the chassis holder 200 may be detachably coupled to a lower portion of the chassis 100. The chassis holder 200 may be provided to cover a portion of the chassis 100 as the chassis holder 200 is coupled to the chassis 100. As will be described later, the chassis holder 200 may be coupled to or separated from the chassis 100 by sliding relative to the chassis 100. For example, the chassis holder 200 may be slidable relative to the chassis 100 in the second direction D2. The chassis holder 200 may be provided to form another portion of the rear exterior of the display apparatus 1.

The chassis holder 200 may be provided to cover the first printed circuit board 30. As the chassis holder 200 is coupled to the chassis 100 in a state in which the first printed circuit board 30 is coupled to the rear side 100a of the chassis 100, the chassis holder 200 may cover the first printed circuit board 30. As a result, the first printed circuit board 30 may not be exposed to the outside of the display apparatus 1.

For example, the chassis holder 200 may be formed through injection molding. The chassis holder 200 may be an injection molded product. The chassis holder 200 may include a plastic material.

The chassis 100 and the chassis holder 200 may be provided to support and/or fix various components of the display apparatus 1 while the chassis 100 and the chassis holder 200 are coupled to each other. The chassis 100 and the chassis holder 200 may be coupled to each other to support and/or fix the display panel 20 and the backlight unit 60.

The chassis 100 and the chassis holder 200 may be provided to cover the borders (e.g., the upper border 20a, the lower border 20b, the left border 20c, and the right border 20d) of the display panel 20. For example, the chassis 100 may be provided to cover the upper border 20a and both side borders (e.g., the left border 20c and the right border 20d) of the display panel 20 (refer to FIGS. 1 and 2). For example, the chassis holder 200 may be provided to cover the lower border 20b of the display panel 20 (refer to FIGS. 1 and 2). The display apparatus 1 may not include a separate bezel or middle mold. As a result, the number of components of the display apparatus 1 may be reduced, and the display apparatus 1 may have a simpler structure compared to other display apparatuses.

The display apparatus 1 may include a rear cover 300. The rear cover 300 may be arranged at the rear of the chassis 100 and the chassis holder 200. The rear cover 300 may be configured to be coupleable to the rear side 100a of the chassis 100 and a rear side 200a of the chassis holder 200 while the chassis holder 200 is coupled to the chassis 100. The chassis holder 200 may be first coupled to the chassis 100, and then the rear cover 300 may be coupled to the chassis holder 200 and the chassis 100 that are coupled to each other. The rear cover 300 may be provided to form another portion of the rear exterior of the display apparatus 1.

The rear cover 300 may be provided to cover the second printed circuit board 40. The chassis holder 200 may cover the second printed circuit board 40 as the rear cover 300 is coupled to the chassis 100 and the chassis holder 200 in a state in which the second printed circuit board 40 is coupled to the rear side 100a of the chassis 100. As a result, the second printed circuit board 40 may not be exposed to the outside of the display apparatus 1.

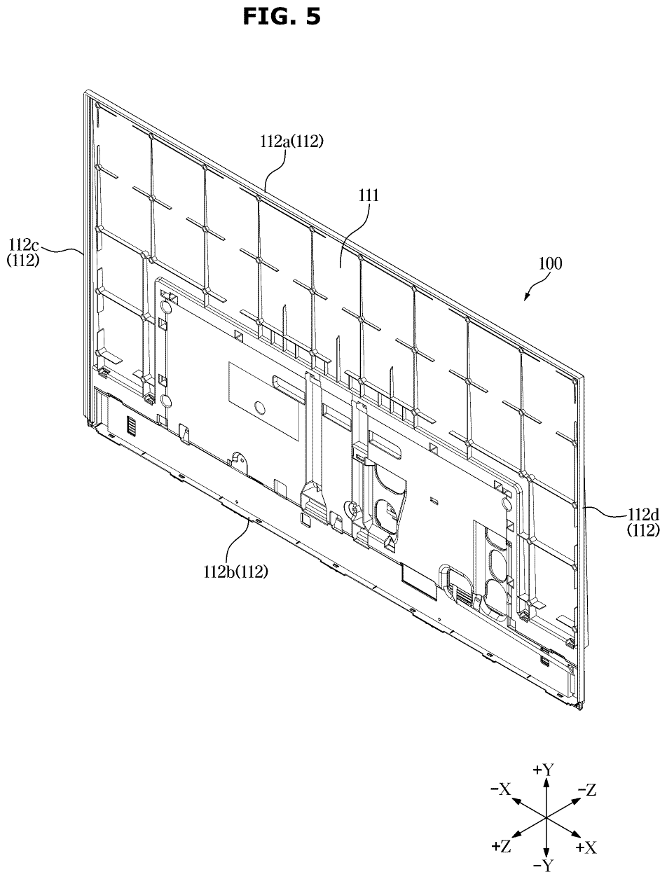

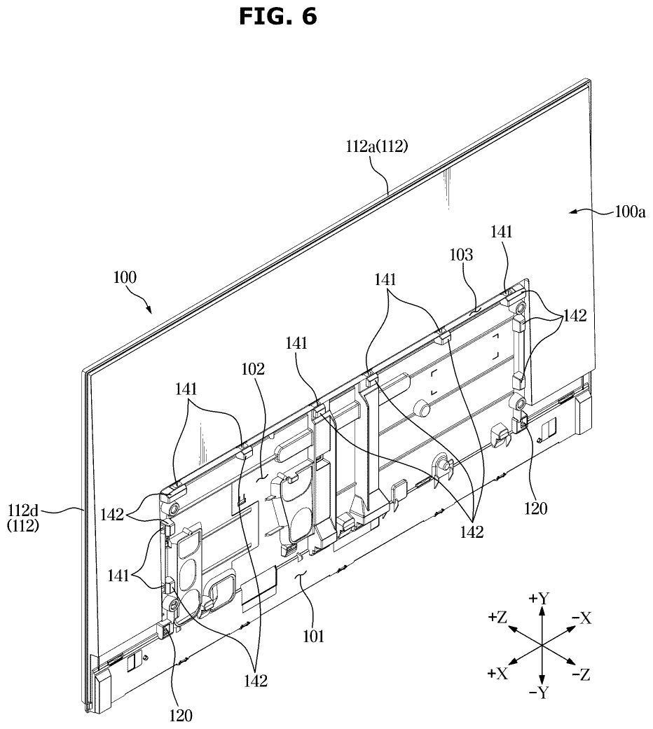

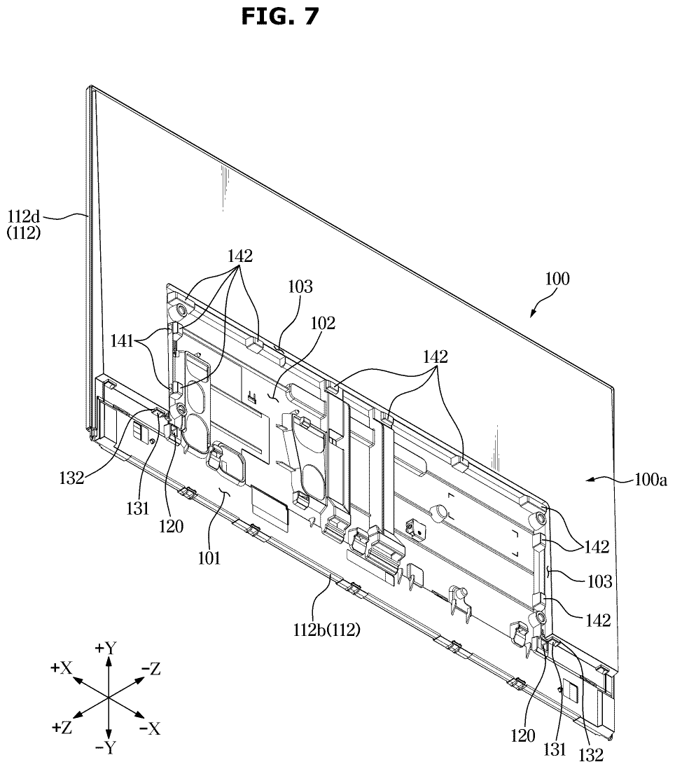

FIG. 5 illustrates a chassis according to an embodiment of the present disclosure. FIG. 6 illustrates the chassis illustrated in FIG. 5 when viewed from a direction different from FIG. 5. FIG. 7 illustrates the chassis illustrated in FIG. 5 when viewed from a direction different from FIGS. 5 and 6.

The chassis 100 may have a shape for supporting various components of the display apparatus 1 (e.g., the display panel 20, the backlight unit 60, the first printed circuit board 30, and the second printed circuit board 40).

The chassis 100 may include a chassis body 111 and an edge portion 112 extending forward from a border of the chassis body 111. For example, the chassis body 111 may have a substantially quadrangle plate shape, and the edge portion 112 may have a substantially quadrangle ring shape.

For example, the edge portion 112 of the chassis 100 may be provided to correspond to each border of the display panel 20 (refer to FIGS. 3 and 4). The chassis 100 may include a first edge portion 112a, a second edge portion 112b, a third edge portion 112c, and a fourth edge portion 112d. The first edge portion 112a may correspond to the upper border 20a of the display panel 20. The first edge portion 112a may cover the upper border 20a of the display panel 20. The second edge portion 112b may correspond to the lower border 20b of the display panel 20. The second edge portion 112b may support the light source device 61 of the backlight unit 60. The third edge portion 112c may correspond to the left border 20c of the display panel 20. The third edge portion 112c may cover the left border 20c of the display panel 20. The fourth edge portion 112d may correspond to the right border 20d of the display panel 20. The fourth edge portion 112d may cover the right border 20d of the display panel 20.

The chassis 100 may include the first mounting portion 101. The first printed circuit board 30 may be detachably coupled to the first mounting portion 101. The first printed circuit board 30 may be fixed to the first mounting portion 101. The first mounting portion 101 may be formed at the rear side 100a of the chassis 100. The first mounting portion 101 may be a portion of a rear surface of the chassis 100 that is recessed forward.

The chassis 100 may include a second mounting portion 102. The second printed circuit board 40 may be detachably coupled to the second mounting portion 102. The second printed circuit board 40 may be fixed to the second mounting portion 102. The second mounting portion 102 may be formed at the rear side 100a of the chassis 100. The second mounting portion 102 may be a portion of the rear surface of the chassis 100 that is recessed forward.

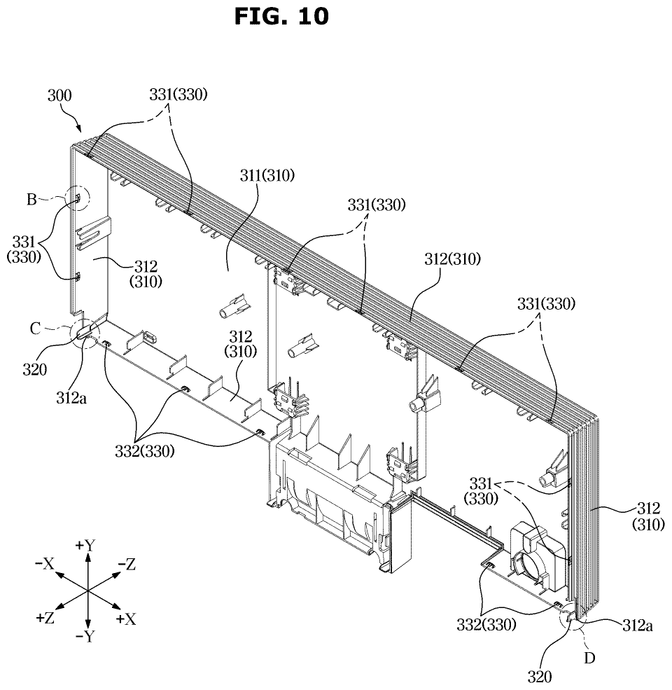

The chassis 100 may include a guide groove 103. The guide groove 103 may be formed at the rear side 100a of the chassis 100. The guide groove 103 may have a shape corresponding to the rear cover 300. For example, the guide groove 103 may have a shape corresponding to at least a portion of a wall portion 312 (refer to FIG. 10) of the rear cover 300 to be described later. The guide groove 103 may be provided to guide the position of the rear cover 300. Accordingly, the rear cover 300 may be easily and accurately disposed at a coupling position. The rear cover 300 and the chassis 100 may be coupled more easily. For example, the time, manpower, and the like for coupling the rear cover 300 to the chassis 100 may be reduced.

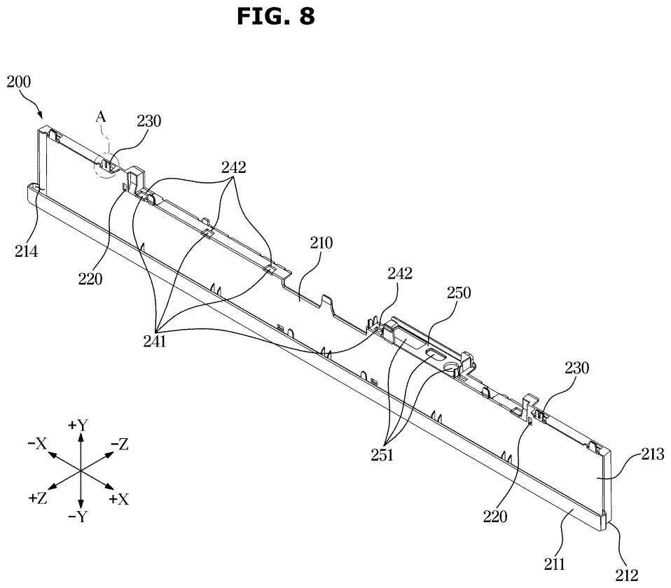

The chassis 100 may include a first rib hole 120. The first rib hole 120 may be provided to correspond to a second rib hole 220 (refer to FIG. 8) of the chassis holder 200 to be described later. The first rib hole 120 may be provided to correspond to a rib 320 (refer to FIG. 10) of the rear cover 300 to be described later. The first rib hole 120 may be provided to allow the rib 320 of the rear cover 300 to be inserted therein. The first rib hole 120 may be formed at the rear side 100a of the chassis 100. The first rib hole 120 may have a shape that is open rearward.

Although it is illustrated that two first rib holes 120 are provided, there is no limitation on the number of first rib holes 120 according to embodiments of the present disclosure.

The chassis 100 may include a coupling hole 131. The coupling hole 131 may be provided to correspond to a coupling protrusion 230 (refer to FIG. 8) of the chassis holder 200 to be described later. The coupling hole 131 may be provide to receive the coupling protrusion 230 of the chassis holder 200. The coupling hole 131 may have a shape that is open downward. The chassis 100 may include a protrusion locking portion 132 (e.g., a protrusion coupling portion). The coupling hole 131 may be provided in the protrusion locking portion 132. The protrusion locking portion 132 may be provided to interfere with the coupling protrusion 230 received in the coupling hole 131.

Although it is illustrated that two coupling holes 131 and two protrusion locking portions 132 are provided, there is no limitation on the number of coupling holes 131 and protrusion locking portions 132 according to embodiments of the present disclosure.

The chassis 100 may include a first hook hole 141. The first hook hole 141 may be provided to correspond to a first hook 331 (refer to FIG. 10) of the rear cover 300 to be described later. The first hook hole 141 may be provided to receive the first hook 331 of the rear cover 300. The chassis 100 may include a first hook locking portion 142. The first hook hole 141 may be provided in the first hook locking portion 142. The first hook locking portion 142 may be provided to interfere with the first hook 331 received in the first hook hole 141.

In the drawing, it is illustrated that the plurality of first hook holes 141 and first hook locking portions 142 is provided, but there is no limitation on the number of first hook holes 141 and first hook locking portions 142 according to embodiments of the present disclosure.

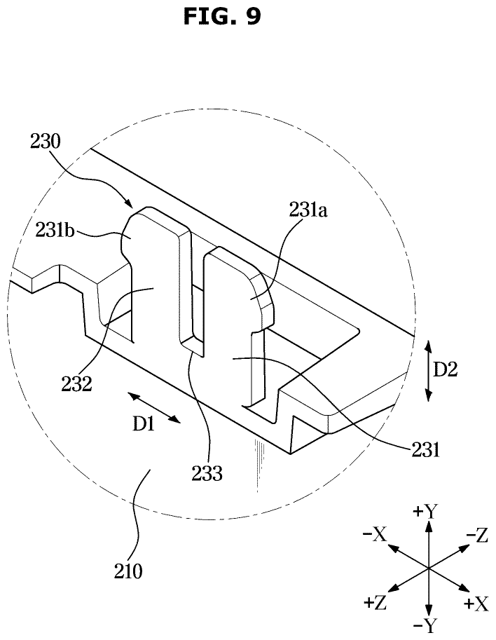

FIG. 8 illustrates a chassis holder according to an embodiment of the present disclosure. FIG. 9 is an enlarged view of a portion A illustrated in FIG. 8.

The chassis holder 200 may include a holder body 210. The holder body 210 may form an overall appearance of the chassis holder 200.

The holder body 210 may be provided to cover a portion of the chassis 100 that supports various components of the display apparatus 1 (refer to FIGS. 1 and 2). For example, the holder body 210 may include a first cover portion 211, a second cover portion 212, and a third cover portion 213. For example, the first cover portion 211 may cover a portion of a front side of the display panel 20, and a portion of a front side of the chassis 100. For example, the second cover portion 212 may cover the second edge portion 112b of the chassis 100. For example, the third cover portion 213 may cover a portion of the rear side 100a of the chassis 100. For example, the third cover portion 213 may cover the first mounting portion 101 of the chassis 100. The first cover portion 211, the second cover portion 212, and the third cover portion 213 may have a substantially “U” shape.

The holder body 210 may include a holder space 214. The holder space 214 may be provided to receive a portion of the lower portion of the chassis 100 that supports various components of the display apparatus 1. For example, the holder space 214 may include a space defined by the first cover portion 211, the second cover portion 212, and the third cover portion 213.

The chassis holder 200 may include a second rib hole 220. The second rib hole 220 may be provided to correspond to the first rib hole 120 (refer to FIGS. 6 and 7) of the chassis 100. The second rib hole 220 may be provided to correspond to the rib 320 (refer to FIG. 10) of the rear cover 300. The second rib hole 220 may be provided to allow the rib 320 of the rear cover 300 to be inserted therein. The second rib hole 220 may be formed to penetrate the holder body 210.

Although it is illustrated that two second rib holes 220 are provided, there is no limitation on the number of second rib holes 220 according to embodiments of the present disclosure.

The chassis holder 200 may include the coupling protrusion 230. The coupling protrusion 230 may be provided to correspond to the coupling hole 131 (refer to FIG. 7) of the chassis 100. The coupling protrusion 230 may be received in the coupling hole 131 of the chassis 100. The coupling protrusion 230 may be provided to be insertable into the coupling hole 131. The coupling protrusion 230 may extend along a sliding direction of the chassis holder 200 (e.g., the second direction D2). For example, the coupling protrusion 230 may extend upward (e.g., +Y direction) from the holder body 210.

The coupling protrusion 230 may include a first protrusion body 231 and a second protrusion body 232. The second protrusion body 232 may be spaced apart from the first protrusion body 231. For example, the second protrusion body 232 may be spaced apart from the first protrusion body 231 along the first direction D1. For example, the first protrusion body 231 and the second protrusion body 232 may be arranged along a substantially horizontal direction (e.g., X direction). For example, the first protrusion body 231 may include a first protrusion 231a that protrudes in one direction, and the second protrusion body 232 may include a second protrusion 231b that protrudes in a direction opposite to the first protrusion 231a. For example, the first protrusion 231a may protrude to the left, and the second protrusion 231b may protrude to the right. For example, a shape of the first protrusion body 231 and a shape of the second protrusion body 232 may be symmetrical respect to each other around an axis that extends in a substantially vertical direction (e.g., the Y-direction).

The first protrusion body 231 and the second protrusion body 232 may be configured to be elastically deformable. Accordingly, a distance between the first protrusion body 231 and the second protrusion body 232 may be varied. A detailed description thereof will be provided below.

The coupling protrusion 230 may include a connecting portion 233 connecting the first protrusion body 231 and the second protrusion body 232. The connecting portion 233 may be arranged between the first protrusion body 231 and the second protrusion body 232. The coupling protrusion 230 may include a substantially “U”shape.

Although it is illustrated that two coupling protrusions 230 are provided, there is no limitation on the number of coupling protrusions 230 according to embodiments of the present disclosure.

The chassis holder 200 may include a second hook hole 241. The second hook hole 241 may be provided to correspond to a second hook 332 (refer to FIG. 10) of the rear cover 300 to be described later. The second hook hole 241 may be provided to receive the second hook 332 of the rear cover 300. The chassis holder 200 may include a second hook locking portion 242. The second hook locking portion 242 may include the second hook hole 241. The second hook locking portion 242 may be provided to interfere with the second hook 332 received in the second hook hole 241.

In the drawing, it is illustrated that a plurality of second hook holes 241 and second hook locking portions 242 is provided, but there is no limitation on the number of second hook holes 241 and second hook locking portions 242 according to embodiments of the present disclosure.

The chassis holder 200 may include a terminal bracket 250. The terminal bracket 250 may be provided to protect various terminals of the display apparatus 1. The terminal bracket 250 may be provided to protect the input terminal 41 (refer to FIG. 2) and/or the power terminal 42 (refer to FIG. 2). The terminal bracket 250 may be provided to fix the input terminal 41 (refer to FIG. 2) and/or the power terminal 42 (refer to FIG. 2). The terminal bracket 250 may include a terminal hole 251 corresponding to the terminal (e.g., the input terminal 41 and/or the power terminal 42). The terminals (e.g., the input terminal 41 and/or the power terminal 42) may be inserted into the terminal hole 251. At least one terminal hole 251 may be provided. The number of terminal holes 251 may correspond to the number of terminals (e.g., the input terminal 41 and/or the power terminal 42).

The terminal bracket 250 may extend from the holder body 210. For example, the terminal bracket 250 may extend approximately vertically from the third cover portion 213. For example, the terminal bracket 250 may extend rearwardly (e.g., in the-Z direction) from the third cover portion 213. Because the terminal bracket 250 is provided as a component of the chassis holder 200, the display apparatus 1 may not include a separate member for protecting the terminal. Accordingly, it is possible to reduce the number of components of the display apparatus 1.

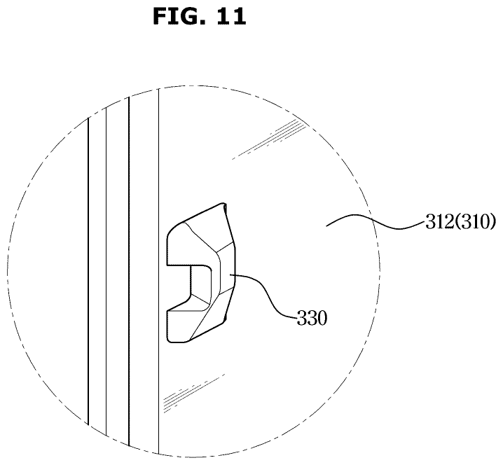

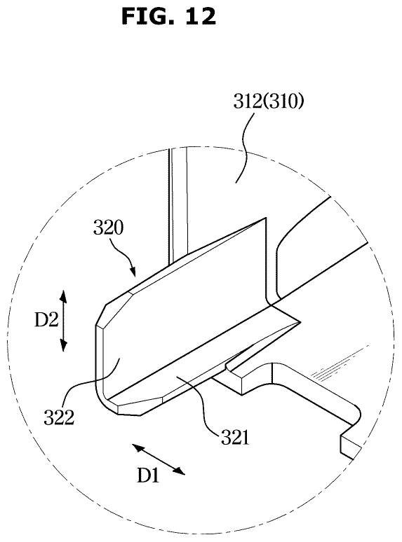

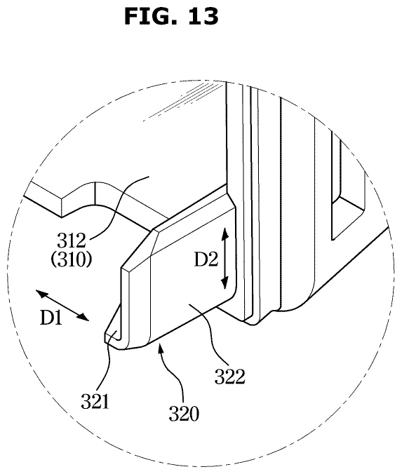

FIG. 10 illustrates a rear cover according to an embodiment of the present disclosure. FIG. 11 is an enlarged view of a portion B illustrated in FIG. 10. FIG. 12 is an enlarged view of a portion C illustrated in FIG. 10. FIG. 13 is an enlarged view of a portion D illustrated in FIG. 10.

The rear cover 300 may include a cover frame 310. The cover frame 310 may form an overall appearance of the rear cover 300. For example, the cover frame 310 may include a box shape in which a front side is open.

The rear cover 300 may include a plate portion 311, and the wall portion 312. The cover frame 310 may include the plate portion 311 and the wall portion 312. The plate portion 311 may be spaced apart from the rear side 100a of the chassis 100 and the rear side 200a of the chassis holder 200 while the rear cover 300 is coupled to the chassis 100 and the chassis holder 200. For example, the plate portion 311 may include a substantially quadrangle shape. The wall portion 312 may extend forward from at least a portion of a border of the plate portion 311. For example, the wall portion 312 may correspond to the shape of the plate portion 311. For example, the wall portion 312 may include a substantially quadrangle tube shape.

The rear cover 300 may include the rib 320. The rib 320 may be provided to correspond to the first rib hole 120 (refer to FIGS. 6 and 7) of the chassis 100. The rib 320 may be configured to be insertable into the first rib hole 120 of the chassis 100. The rib 320 may be provided to correspond to the second rib hole 220 (refer to FIG. 8) of the chassis holder 200. The rib 320 may be configured to be insertable into the second rib hole 220 of the chassis holder 200. The rib 320 may be inserted into the first rib hole 120 and the second rib hole 220 that overlap with each other.

The rib 320 may be formed on the cover frame 310. The rib 320 may be formed on the wall portion 312. The rib 320 may protrude from the wall portion 312. The rib 320 may protrude forward from the wall portion 312. For example, the rib 320 may protrude from a corner 312a of the wall portion 312.

The rib 320 may include a first extension portion 321 extending in the first direction D1. The rib 320 may include a second extension portion 322 extending in the second direction D2. The second extension portion 322 may extend from the first extension portion 321 in the second direction D2. The first extension portion 321 and the second extension portion 322 may be provided to be approximately perpendicular to each other. For example, the first extension portion 321 and the second extension portion 322 may be provided to be connected at the corner 312a of the wall portion 312.

Although it is illustrated that two ribs 320 are provided, there is no limitation on the number of ribs 320 according to embodiments of the present disclosure.

The rear cover 300 may include at least one hook 330. The at least one hook 330 may be formed on the cover frame 310. The at least one hook 330 may be provided to be detachably coupled to the chassis 100 and/or the chassis holder 200. The at least one hook 330 may be fixed to the chassis 100 and/or the chassis holder 200. The at least one hook 330 may include at least one first hook 331 and at least one second hook 332.

The rear cover 300 may include the first hook 331. The first hook 331 may be provided to correspond to the first hook hole 141 (refer to FIGS. 6 and 7) of the chassis 100. The first hook 331 may be received in the first hook hole 141 of the chassis 100. The first hook 331 may be provided to be insertable into the first hook hole 141. The first hook 331 may be inserted into the first hook hole 141 and may come into contact with the first hook locking portion 142.

The first hook 331 may be formed on the cover frame 310. The first hook 331 may be formed on the wall portion 312. The first hook 331 may protrude from the wall portion 312. For example, the first hook 331 may be formed on an inner surface of the wall portion 312. For example, the first hook 331 may be formed on an upper inner surface of an upper portion and inner surfaces of both sides of the wall portion 312.

Although it is illustrated that a plurality of first hooks 331 is spaced apart and arranged along the inner surface of the wall portion 312, embodiments of the present disclosure are not limited thereto. There is no limitation on the position and the number of first hooks 331.

The rear cover 300 may include the second hook 332. The second hook 332 may be spaced apart from the first hook 331. The second hook 332 may be provided to correspond to the second hook hole 241 (refer to FIGS. 6 and 7) of the chassis holder 200. The second hook 332 may be received in the second hook hole 241 of the chassis holder 200. The second hook 332 may be provided to be insertable into the second hook hole 241. The second hook 332 may be inserted into the second hook hole 241 and may come into contact with the second hook locking portion 242.

The second hook 332 may be formed on the cover frame 310. The second hook 332 may be formed on the wall portion 312. The second hook 332 may protrude from the wall portion 312. For example, the second hook 332 may be formed on the inner surface of the wall portion 312. For example, the second hook 332 may be formed on a lower inner surface of the wall portion 312.

Although it is illustrated that a plurality of second hooks 332 is spaced apart and arranged along the inner surface of the wall portion 312, embodiments of the present disclosure are not limited thereto. There is no limitation on the position and number of second hooks 332.

The first hook 331 may be coupled to the chassis 100, and the second hook 332 may be coupled to the chassis holder 200. The first hook 331 and the second hook 332 may be different only in the coupling target, and the shape of the first hook 331 and the shape of the second hook 332 may be substantially the same as each other. However, the shape of the first hook 331 and the shape of the second hook 332 may be different from each other.

An assembly process of the display apparatus will be described with reference to FIGS. 14 to 21. A separation (disassembly) process of the display apparatus may be performed in the reverse order of the assembly process described with reference to FIGS. 14 to 21.

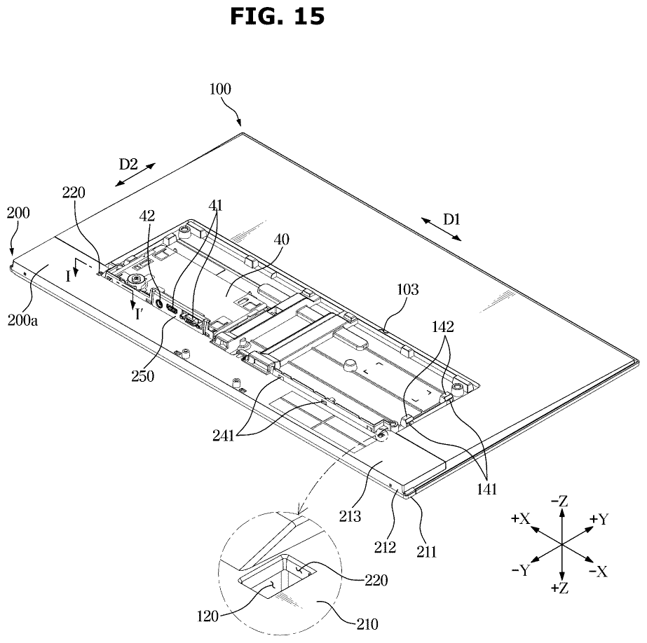

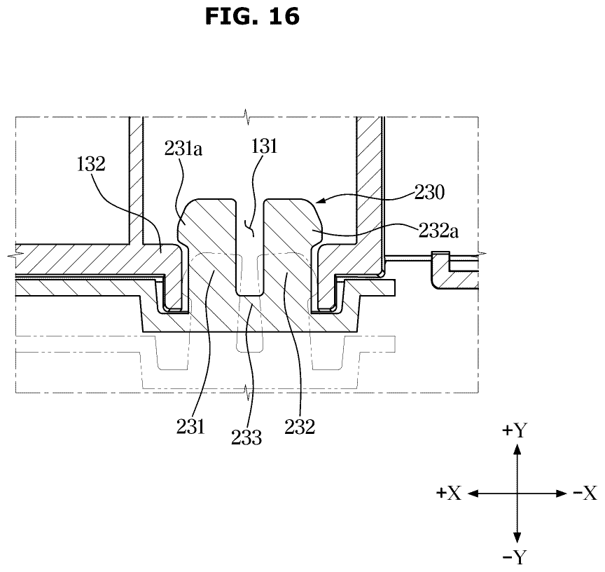

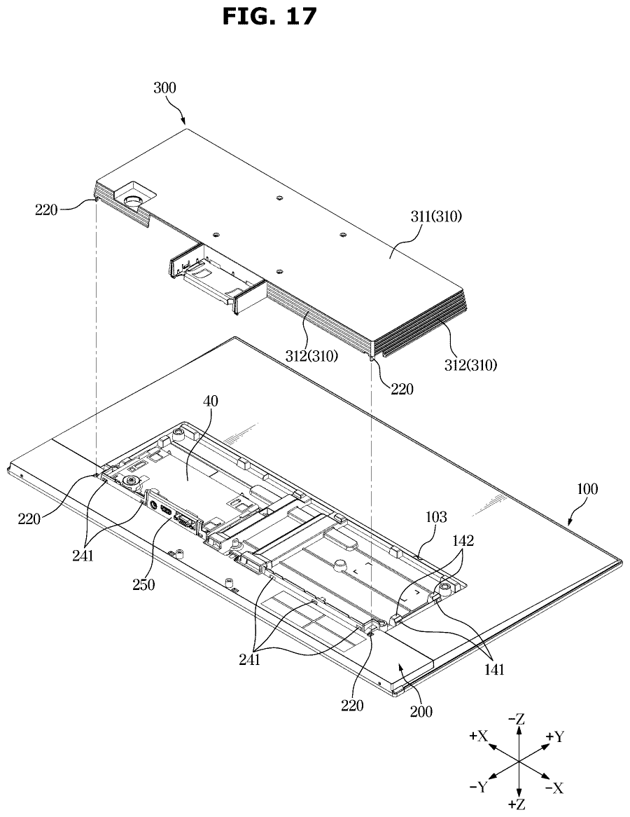

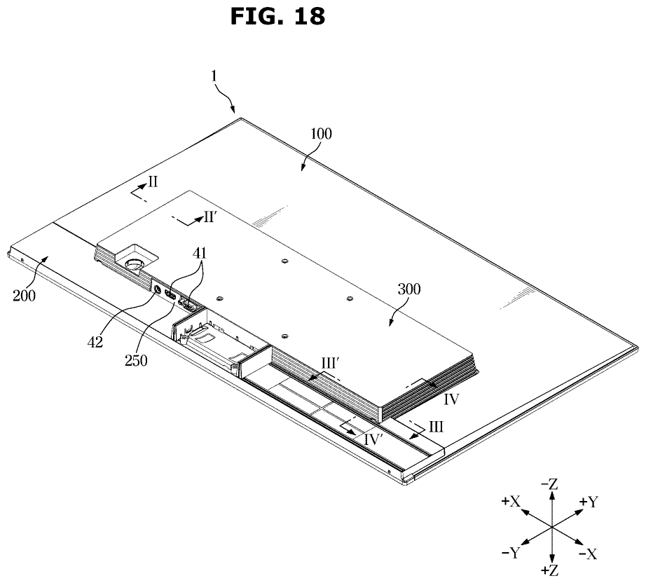

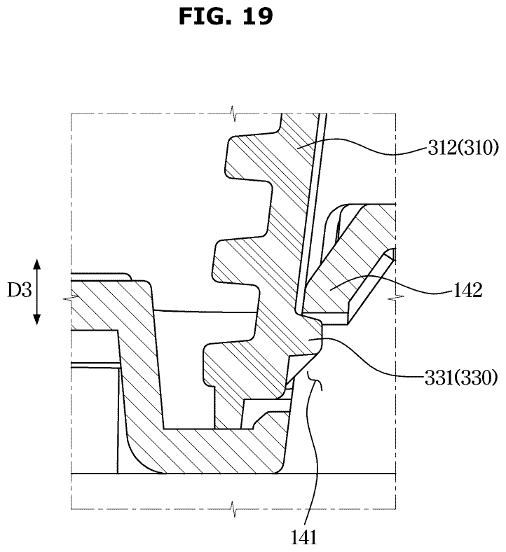

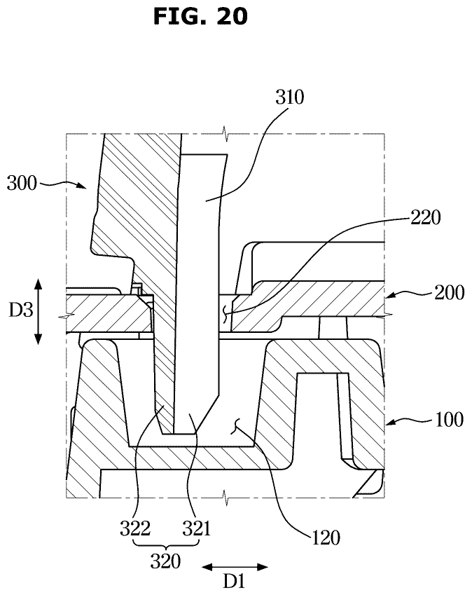

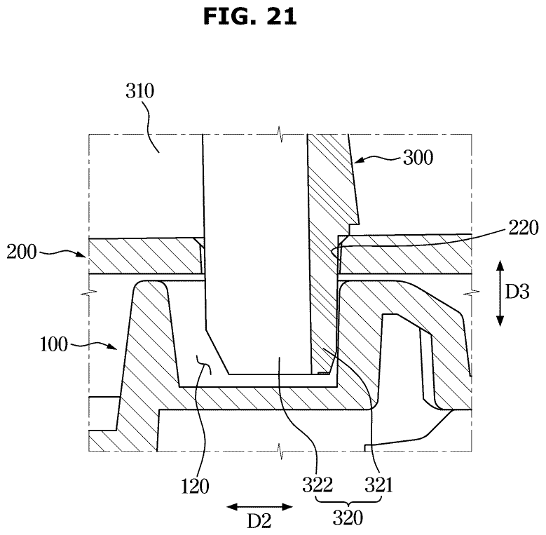

FIG. 14 illustrates a state in which the chassis holder is separated from the chassis in the display apparatus according to an embodiment of the present disclosure. FIG. 15 illustrates a state in which the chassis holder is coupled to the chassis in the display apparatus according to an embodiment of the present disclosure. FIG. 16 is a cross-sectional view taken along a line I-I′ illustrated in FIG. 15. FIG. 17 illustrates a state in which the rear cover is separated from the chassis and the chassis holder in the display apparatus according to an embodiment of the present disclosure. FIG. 18 illustrates a state in which the rear cover is coupled to the chassis and the chassis holder in the display apparatus according to an embodiment of the present disclosure. FIG. 19 is a cross-sectional view taken along a line II-II′ illustrated in FIG. 18. FIG. 20 is a cross-sectional view taken along a line III-III′ illustrated in FIG. 18. FIG. 21 is a cross-sectional view taken along a line IV-IV′ illustrated in FIG. 18.

Referring to FIGS. 14 to 16, the chassis holder 200 may be coupleable to the chassis 100.

The chassis holder 200 may be coupled to the chassis 100 or separated from the chassis 100 by sliding relative to the chassis 100 (refer to an arrow S in FIG. 14). For example, the chassis holder 200 may be movable substantially along the second direction D2 relative to the chassis 100.

As the coupling protrusion 230 of the chassis holder 200 is inserted into the coupling hole 131 of the chassis 100, the chassis holder 200 may be coupled to the chassis 100. As the coupling protrusion 230 of the chassis holder 200 is separated from the coupling hole 131 of the chassis 100, the chassis holder 200 may be separated from the chassis 100.

The coupling protrusion 230 may be elastically deformed to be inserted into the coupling hole 131. For example, while the coupling protrusion 230 is being inserted into the coupling hole 131, a distance between the first protrusion body 231 and the second protrusion body 232 may be reduced (refer to a dashed line in FIG. 16). For example, when the coupling protrusion 230 is completely inserted into the coupling hole 131, the distance between the first protrusion body 231 and the second protrusion body 232 may return to its original state (refer to a solid line in FIG. 16). Conversely, the coupling protrusion 230 received in the coupling hole 131 may be elastically deformed to be pulled out of the coupling hole 131. For example, while the coupling protrusion 230 is being separated from the coupling hole 131, the distance between the first protrusion body 231 and the second protrusion body 232 may be reduced (refer to the dashed line in FIG. 16). For example, when the coupling protrusion 230 is completely separated from the coupling hole 131, the distance between the first protrusion body 231 and the second protrusion body 232 may return to the original state.

While the chassis holder 200 is coupled to the chassis 100, the coupling protrusion 230 may be received in the coupling hole 131. The coupling protrusion 230 received in the coupling hole 131 may interfere with the protrusion locking portion 132. The coupling protrusion 230 received in the coupling hole 131 may not be easily separated from the coupling hole 131 by the protrusion locking portion 132. In addition, the movement of the coupling protrusion 230 received in the coupling hole 131 in the first direction D1, the second direction D2, and the third direction D3 may be restricted by the protrusion locking portion 132. As a result, the coupling strength between the chassis 100 and the chassis holder 200 may be increased.

While the chassis holder 200 is coupled to the chassis 100, the first rib hole 120 of the chassis 100 may be provided to correspond to the second rib hole 220 of the chassis holder 200. While the chassis 100 and the chassis holder 200 are coupled, the first rib hole 120 of the chassis 100 and the second rib hole 220 of the chassis holder 200 may overlap.

While the chassis holder 200 is coupled to the chassis 100, the terminal bracket 250 of the chassis holder 200 may correspond to the terminals (e.g., the input terminal 41 and/or the power terminal 42) of the second printed circuit board 40. The terminals (e.g., the input terminal 41 and/or the power terminal 42) may be inserted into the terminal holes 251 of the chassis holder 200.

As the chassis holder 200 is coupled to the chassis 100, the chassis holder 200 may cover the first printed circuit board 30 mounted on the chassis 100. As the chassis holder 200 is coupled to the chassis 100, the chassis holder 200 may cover the film cable 50. The film cable 50 may be bent to connect the display panel 20 and the first printed circuit board 30. For example, the film cable 50 may have a substantially ‘U’ shape. While the chassis holder 200 is coupled to the chassis 100, the chassis holder 200 may cover a front side 51, a lower side 52, and a rear side 53 of the film cable 50. Accordingly, the chassis holder 200 may prevent the first printed circuit board 30 and the film cable 50 from being exposed to the outside and may protect the first printed circuit board 30 and the film cable 50.

Referring to FIGS. 17 to 21, the rear cover 300 may be coupleable to the chassis 100 and the chassis holder 200. After the chassis holder 200 is coupled to the chassis 100, the rear cover 300 may be coupled to the rear side of the chassis 100 and the rear side of the chassis holder 200.

The rear cover 300 may be coupled to the chassis 100 and the chassis holder 200 while moving toward the chassis 100 and the chassis holder 200. The rear cover 300 may be coupled to the rear side 100a of the chassis 100 and the rear side 200a of the chassis holder 200 while moving approximately forward. The guide groove 103 of the chassis 100 may guide the position of the rear cover 300.

The hooks 330 of the rear cover 300 may be coupled to the chassis 100 and the chassis holder 200. The first hook 331 may be received in the first hook hole 141 and interfere with the first hook locking portion 142. For example, the first hook 331 may be provided to come into contact with the first hook locking portion 142 with respect to the third direction D3 (refer to FIG. 19). The first hook 331 may be configured to be locked to the first hook locking portion 142 while the first hook 331 is received in the first hook hole 141. Accordingly, the movement of the first hook 331 in the third direction D3 may be restricted. Similarly, the second hook 332 may be received in the second hook hole 241 and interfere with the second hook locking portion 242. For example, the second hook 332 may be provided to come into contact with the second hook locking portion 242 with respect to the direction D3. The second hook 332 may be configured to lock to the second hook locking portion 242 while the second hook 332 is received in the second hook hole 241. Accordingly, the movement of the second hook 332 in the third direction D3 may be restricted.

While the rear cover 300 is coupled to the chassis 100 and the chassis holder 200, the rib 320 may be inserted into the first rib hole 120 of the chassis 100 and the second rib hole 220 of the chassis holder 200. The rib 320 may be inserted into the second rib hole 220 and the first rib hole 120 by being received in the first rib hole 120 through the second rib hole 220. The rib 320 may be disposed within the first rib hole 120 and the second rib hole 220.

The rib 320 may include the first extension portion 321 extending in the first direction D1, and the second extension portion 322 extending in the second direction D2. Due to the shape thereof, the rib 320 may be restricted from moving in the first direction D1 and the second direction D2 while being received in the first rib hole 120 and the second rib hole 220. For example, the first extension portion 321 may be restricted from moving in the first direction D1 while being received in the first rib hole 120 and the second rib hole 220. For example, the second extension portion 322 may be restricted from moving in the second direction D2 while being received in the first rib hole 120 and the second rib hole 220.

As the rear cover 300 is coupled to the chassis 100 and the chassis holder 200, the rear cover 300 may cover the second printed circuit board 40 mounted on the chassis 100. The rear cover 300 may prevent the second printed circuit board 40 from being exposed to the outside and may protect the second printed circuit board 40.

In general, components for supporting a display panel and/or a backlight unit may be coupled by screws. Accordingly, the structure of a display apparatus may be complicated and the number of components of the display apparatus may be increased in a comparative embodiment. In addition, the assembly work of the display apparatus of the comparative embodiment may take a lot of time and cost. Meanwhile, components for supporting the display panel and/or the backlight unit of the comparative embodiment may be easily separated due to external impact or vibration. For example, when it is assumed that the display apparatus of the comparative embodiment includes a first component, a second component, and a third component, a method, in which the first component and the second component are coupled and the first component and the third component are coupled, may generally be used. When the first component, the second component, and the third component are assembled, errors thereof may accumulate, resulting in an increase in the accumulated tolerance. As a result, the assembly quality of the display apparatus of the comparative embodiment may deteriorate.

According to embodiments of the present disclosure, the chassis 100, the chassis holder 200, and the rear cover 300 of the display apparatus 1 may be assembled without a screw. As a result, the structure of the display apparatus 1 may be simplified and the number of components of the display apparatus 1 may be reduced. In addition, the productivity of the display apparatus 1 may be improved. According to embodiments of the present disclosure, the rib 320 may be inserted into the first rib hole 120 and the second rib hole 220, which overlap with each other, at once. As the rib 320 is inserted into the first rib hole 120 and the second rib hole 220 at once, the positions of the rear cover 300, the chassis 100, and the chassis holder 200 may be adjusted, respectively. As a result, when assembling the chassis 100, the chassis holder 200, and the rear cover 300, the accumulated tolerance may be reduced compared to a method of a comparative embodiment. In addition, because the rib 320 is simultaneously received in the first rib hole 120 and the second rib hole 220, the coupling strength of the chassis 100, the chassis holder 200, and the rear cover 300 may be increased. The rib 320 may be restricted from moving in the first direction D1 and the second direction D2 while received in the first rib hole 120 and the second rib hole 220 (refer to FIGS. 20 and 21). The chassis 100, the chassis holder 200, and the rear cover 300 may not be easily separated even by external impact or vibration. As a result, the assembling efficiency of the display apparatus 1 may be increased.

The display apparatus 1 according to an embodiment of the present disclosure may include the display panel 20; the chassis 100 provided to cover the rear side of the display panel 20 and provided to support the display panel 20; the chassis holder 200 coupleable to the lower portion of the chassis 100; and the rear cover 300 coupleable to the rear side 100a of the chassis and the rear side 200a of the chassis holder while the chassis holder 200 is coupled to the chassis 100. The chassis 100 may include the first rib hole 120. The chassis holder 200 may include the second rib hole 220 provided to correspond to (e.g., overlap with) the first rib hole 120 while the chassis holder is coupled to the chassis. The rear cover 300 may include the rib 320 inserted into the second rib hole 220 and the first rib hole 120 by being received in the first rib hole 120 through the second rib hole 220 while the rear cover is coupled to the chassis and the chassis holder.

The display apparatus may further include the first printed circuit board 30 positioned on the rear side 100a of the chassis 100 and configured to control the display panel 20, and the film cable 50 provided to be bent to connect the display panel 20 and the first printed circuit board 30. The chassis holder 200 may be provided to cover the first printed circuit board 30 and the front side 51, the lower side 52 and the rear side 53 of the film cable 50 while the chassis holder 200 is coupled to the chassis 100.

The chassis holder 200 may be configured to be coupled to or separated from the chassis 100 by sliding relative to the chassis 100.

The display panel 20 may include the pair of first sides 21 extending along the first direction D1, and the pair of second sides 22 extending along the second direction D2. The rib 320 of the rear cover 300 may include the first extension portion 321 extending in the first direction, and the second extension portion 322 extending from the first extension portion to the second direction.

The rear cover 300 may include the plate portion 311 spaced apart from the rear side of the chassis 100 and the rear side of the chassis holder 200 while the rear cover is coupled to the chassis 100 and the chassis holder 200, and the wall portion 312 extending forward from at least a portion of the border of the plate portion 311.

The rib 320 may protrude from the wall portion 312.

The plate portion 311 may include a quadrangle shape, and the wall portion 312 may correspond to the shape of the plate portion. The rib 320 may protrude from the corner 312a of the wall portion 312.

The rear cover 300 may further include the first hook 331 formed on the inner surface of the wall portion, and the second hook 332 formed on the inner surface of the wall portion and spaced apart from the first hook. The chassis 100 may include the first hook hole 141 provided to receive the first hook while the rear cover is coupled to the chassis and the chassis holder, and the first hook locking portion 142 provided to form the first hook hole and provided to interfere with the first hook. The chassis holder 200 may include the second hook hole 241 provided to receive the second hook while the rear cover is coupled to the chassis and the chassis holder, and the second hook locking portion 242 provided to form the second hook hole and provided to interfere with the second hook.

The display panel 20 may include the pair of first sides 21 extending along the first direction D1, and the pair of second sides 22 extending along the second direction D2. The first hook 331 and the first hook locking portion 142 may be provided to come into contact with each other in the third direction D3 intersecting the first direction D1 and the second direction D2. The second hook 332 and the second hook locking portion 242 may be provided to come into contact with each other in the third direction D3.

The chassis holder 200 may further include the coupling protrusion 230 extending along the sliding direction of the chassis holder 200. The chassis 100 may further include the coupling hole 131 provided to receive the coupling protrusion, and the protrusion locking portion 132 provided to form the coupling hole and provided to interfere with the coupling protrusion.

The coupling protrusion 230 may include the first protrusion body 231, and the second protrusion body 232 spaced apart from the first protrusion body. The first protrusion body 231 and the second protrusion body 232 may be elastically deformable to allow a distance between the first protrusion body and the second protrusion body to be variable.

The display apparatus may further include the second printed circuit board 40 disposed on the rear side of the chassis 100 and including the terminal configured to receive a signal and/or power from the outside. The rear cover 300 may be provided to cover the second printed circuit board 40 while the rear cover is coupled to the chassis and the chassis holder.

The chassis holder 200 may further include the terminal bracket 250 provided to protect the terminal and including the terminal hole corresponding to (e.g., configured to receive) the terminal.

The chassis 100 may be provided to cover the upper border 20a and both side borders (e.g., the left border 20c and the right border 20d) of the display panel 20. The chassis holder 200 may be provided to cover the lower border 20b of the display panel 20.

The chassis 100 may be provided to form a portion of the rear exterior of the display apparatus 1. The chassis holder 200 may be provided to form another portion of the rear exterior of the display apparatus 1.

The display apparatus 1 according to an embodiment of the present disclosure may include the display panel 20; the chassis 100 provided to support the display panel 20; the first printed circuit board 30 positioned on the rear side of the chassis and configured to control the display panel 20; the second printed circuit board 40 positioned on the rear side of the chassis 100 and including the terminal configured to receive a signal and/or power from the outside; the chassis holder 200 configured to be coupled to or separated from the chassis by sliding relative to the chassis 100; and the rear cover 300 coupleable to the rear side of the chassis 100 and the rear side of the chassis holder 200 while the chassis holder is coupled to the chassis 100. The chassis holder 200 may be provided to cover the first printed circuit board 30 while the chassis holder 200 is coupled to the chassis 100. The rear cover 300 may be provided to cover the second printed circuit board 40 while the rear cover is coupled to the chassis 100 and the chassis holder 200.

The chassis 100 may include the first rib hole 120. The chassis holder 200 may include the second rib hole 220 provided to correspond to the first rib hole while the chassis holder is coupled to the chassis. The rear cover 300 may include the rib 320 inserted into the second rib hole and the first rib hole by being received in the first rib hole through the second rib hole 220 while the rear cover is coupled to the chassis and the chassis holder.

The display apparatus may further include the film cable 50 provided to be bent to connect the display panel 20 and the first printed circuit board 30. The chassis holder 200 may be provided to cover the front side 51, the lower side 52 and the rear side 53 of the film cable 50 while the chassis holder is coupled to the chassis.

The chassis 100 may be provided to form a portion of the rear exterior of the display apparatus 1. The chassis holder 200 may be provided to form another portion of the rear exterior of the display apparatus 1.

The display panel 20 may include the pair of long sides extending along the first direction D1, and the pair of short sides extending along the second direction D2. The chassis holder 200 may be slidably movable along the second direction D2 relative to the chassis 100.

As is apparent from the above description, assemblability of a display apparatus may be improved.

Further, productivity of a display apparatus may be improved. The number of components of a display apparatus may be reduced. The time and cost required for assembling the display apparatus may be reduced.

While non-limiting example embodiments of the present disclosure have been particularly described above with reference to the accompanying drawings, it should be understood by those of skilled in the art that various changes in form and details may be made without departing from the spirit and scope of the present disclosure.

What is claimed is:

1. A display apparatus comprising:
a display panel;
a chassis configured to cover a rear side of the display panel and support the display panel, the chassis including a first rib hole;
a chassis holder configured to connect to a lower portion of the chassis, the chassis holder including a second rib hole configured to overlap with the first rib hole while the chassis holder is connected to the chassis; and
a rear cover configured to connect to a rear side of the chassis and a rear side of the chassis holder while the chassis holder is connected to the chassis,
wherein the rear cover comprises a rib, the rib being configured to be inserted into the second rib hole and the first rib hole by being received in the first rib hole through the second rib hole while the rear cover is connected to the chassis and the chassis holder.

2. The display apparatus of claim 1, further comprising:
a printed circuit board on the rear side of the chassis, the printed circuit board being configured to control the display panel; and
a film cable configured to connect the display panel and the printed circuit board,
wherein the chassis holder is configured to cover the printed circuit board and a front side, a lower side, and a rear side of the film cable while the chassis holder is connected to the chassis.

3. The display apparatus of claim 1, wherein
the chassis holder is configured to be connected to or separated from the chassis by sliding relative to the chassis.

4. The display apparatus of claim 1, wherein
the display panel comprises:
a pair of first sides extending in a first direction; and
a pair of second sides extending in a second direction that crosses the first direction, and
wherein the rib of the rear cover comprises:
a first extension portion extending in the first direction; and
a second extension portion extending in the second direction from the first extension portion.

5. The display apparatus of claim 1, wherein the rear cover comprises:
a plate portion spaced apart from the rear side of the chassis and the rear side of the chassis holder while the rear cover is connected to the chassis and the chassis holder; and
a wall portion extending forward from at least a portion of a border of the plate portion.

6. The display apparatus of claim 5, wherein
the rib protrudes from the wall portion.

7. The display apparatus of claim 6, wherein
the plate portion comprises a quadrangle shape,
wherein the wall portion comprises a quadrangle tube shape, and
wherein the rib protrudes from a corner of the wall portion.

8. The display apparatus of claim 5, wherein
the rear cover further comprises:
a first hook on an inner surface of the wall portion; and
a second hook on the inner surface of the wall portion and spaced apart from the first hook,
wherein the chassis comprises:
a first hook hole configured to receive the first hook while the rear cover is connected to the chassis and the chassis holder; and
a first hook locking portion including the first hook hole, the first hook locking portion configured to interfere with the first hook, and
wherein the chassis holder comprises:
a second hook hole configured to receive the second hook while the rear cover is connected to the chassis and the chassis holder; and
a second hook locking portion including the second hook hole, the second hook locking portion configured to interfere with the second hook.

9. The display apparatus of claim 8, wherein
the display panel comprises:
a pair of first sides extending in a first direction; and
a pair of second sides extending in a second direction that crosses the first direction,
wherein the first hook and the first hook locking portion are configured to come into contact with each other in a third direction intersecting the first direction and the second direction, and
wherein the second hook and the second hook locking portion are configured to come into contact with each other in the third direction.

10. The display apparatus of claim 3, wherein
the chassis holder further comprises a coupling protrusion extending along a sliding direction of the chassis holder, and
wherein the chassis further comprises:
a coupling hole configured to receive the coupling protrusion; and
a protrusion locking portion that includes the coupling hole, the protrusion locking portion configured to interfere with the coupling protrusion.

11. The display apparatus of claim 10, wherein the coupling protrusion comprises:
a first protrusion body; and
a second protrusion body spaced apart from the first protrusion body, and
wherein the first protrusion body and the second protrusion body are elastically deformable such that a distance between the first protrusion body and the second protrusion body is variable.

12. The display apparatus of claim 1, further comprising:
a printed circuit board on the rear side of the chassis, the printed circuit board comprising a terminal configured to receive a signal or power from an outside of the display apparatus,
wherein the rear cover is configured to cover the printed circuit board while the rear cover is connected to the chassis and the chassis holder.

13. The display apparatus of claim 12, wherein
the chassis holder further comprises a terminal bracket configured to protect the terminal, the terminal bracket comprising a terminal hole that is configured to receive the terminal.

14. The display apparatus of claim 1, wherein
the chassis is configured to cover an upper border and opposite side borders of the display panel, and
wherein the chassis holder is configured to cover a lower border of the display panel.

15. The display apparatus of claim 1, wherein
the chassis is a portion of a rear exterior of the display apparatus, and
wherein the chassis holder is another portion of the rear exterior of the display apparatus.

16. A display apparatus comprising:
a display panel;
a chassis configured to support the display panel;
a first printed circuit board on a rear side of the chassis, the first printed circuit board being configured to control the display panel;
a second printed circuit board on the rear side of the chassis, the second printed circuit board comprising a terminal configured to receive a signal or power from an outside of the display apparatus;
a chassis holder configured to be connected to or separated from the chassis by sliding relative to the chassis, the chassis holder being further configured to cover the first printed circuit board while the chassis holder is connected to the chassis; and
a rear cover configured to be connected to the rear side of the chassis and a rear side of the chassis holder while the chassis holder is connected to the chassis, the rear cover being further configured to cover the second printed circuit board while the rear cover is connected to the chassis and the chassis holder.

17. The display apparatus of claim 16, further comprising:
a film cable configured to connect the display panel and the first printed circuit board,
wherein the chassis holder is configured to cover a front side, a lower side, and a rear side of the film cable while the chassis holder is connected to the chassis.

18. The display apparatus of claim 16, wherein
the chassis is a portion of a rear exterior of the display apparatus, and
wherein the chassis holder is another portion of the rear exterior of the display apparatus.

19. The display apparatus of claim 16, wherein
the display panel comprises:
a pair of first sides extends in a first direction; and
a pair of second sides extending in a second direction crossing the first direction,
wherein the pair of first sides are longer than the pair of second sides, and
wherein the chassis holder is configured to slidably move in the second direction relative to the chassis.

20. A display apparatus comprising:
a display panel;
a chassis that covers a rear side of the display panel and supports the display panel, the chassis including a first rib hole;
a chassis holder that is connected to a lower portion of the chassis, the chassis holder including a second rib hole that overlaps with the first rib hole; and
a rear cover that is connected to a rear side of the chassis and a rear side of the chassis holder while the chassis holder is connected to the chassis,
wherein the rear cover comprises a rib, the rib being within the second rib hole and the first rib hole by being received in the first rib hole through the second rib hole while the rear cover is connected to the chassis and the chassis holder.
